(19) United States
(12) Patent Application Publication
(10) Pub. No.: US 2018/0096863 A1
(43) Pub. Date: Apr. 5, 2018

(54) SUBSTRATE PROCESSING METHOD, SUBSTRATE PROCESSING APPARATUS, AND STORAGE MEDIUM

(71) Applicant: Tokyo Electron Limited, Tokyo (JP)

(72) Inventors: Gentaro GOSHI, Kumamoto (JP); Hiromi KIYOSE, Kumamoto (JP); Yasuo KIYOHARA, Kumamoto (JP)

(21) Appl. No.: 15/718,369

(22) Filed: Sep. 28, 2017

(30) Foreign Application Priority Data
Oct. 4, 2016 (JP) 2016-196630

(51) Int. Cl. H01L 21/67; B08B 3/08; F26B 5/00

(52) U.S. Cl. CPC H01L 21/67034; F26B 5/005; B08B 3/08

(57) ABSTRACT

Disclosed is a substrate liquid processing method including: a first processing step of discharging a fluid in the processing container until an inside of the processing container reaches a first discharge ultimate pressure at which the processing fluid in the supercritical state is not vaporized, and then supplying the processing fluid into the processing container until the inside of the processing container reaches a first supply ultimate pressure at which vaporization of the processing fluid does not occur; and a second processing step of discharging a fluid in the processing container until the inside of the processing container reaches a second discharge ultimate pressure at which the processing fluid in the supercritical state is not vaporized, and then supplying the processing fluid into the processing container until the inside of the processing container reaches a second supply ultimate pressure at which vaporization of the processing fluid does not occur.

### CROSS-REFERENCE TO RELATED APPLICATIONS

This application is based on and claims priority from Japanese Patent Application No. 2016-196630 filed on Oct. 4, 2016 with the Japan Patent Office, the disclosure of which is incorporated herein in its entirety by reference.

### TECHNICAL FIELD

The present disclosure relates to a technique of removing a liquid attached to a surface of a substrate using a processing fluid in a supercritical state.

### BACKGROUND

In a manufacturing process of a semiconductor device in which a laminated structure of an integrated circuit is formed on the surface of, for example, a semiconductor wafer (hereinafter referred to as a “wafer”) as a substrate, a liquid processing step is provided to process the surface of the water using a liquid, for example, to remove fine dust or a natural oxide film on the surface of the wafer with a cleaning liquid such as, for example, a chemical liquid.

There is known a method of using a processing fluid in a supercritical state when removing, for example, a liquid attached to a surface of a wafer in such a liquid processing step.

For example, Japanese Patent Laid-Open Publication No. 2013-012538 discloses a substrate processing apparatus in which a liquid attached to a substrate is removed by bringing a fluid in a supercritical state into contact with the substrate. Further, Japanese Patent Laid-Open Publication No. 2013-016798 discloses a substrate processing apparatus is which a substrate is dried by dissolving an organic solvent from the substrate using a supercritical fluid.

In a drying processing of removing a liquid from a substrate using a processing fluid in a supercritical state, it is desirable to shorten the processing time as much as possible while suppressing the occurrence of collapse of semiconductor patterns formed on the substrate (i.e., the pattern collapse caused by the surface tension of the liquid between the patterns). In addition, it is desirable to minimize the consumption of the processing fluid used for the drying processing as much as possible.

### SUMMARY

According to an aspect of the present disclosure, there is provided a substrate processing method that performs a drying processing of removing a liquid from a substrate using a processing fluid in a supercritical state in a processing container. The substrate processing method includes a first processing step of discharging a fluid in the processing container until an inside of the processing container reaches a first discharge ultimate pressure at which vaporization of the processing fluid in the supercritical state present in the processing container does not occur, and then supplying the processing fluid into the processing container until the inside of the processing container reaches a first supply ultimate pressure which is higher than the first discharge ultimate pressure and at which vaporization of the processing fluid in the processing container does not occur; and after the first processing step, a second processing step of discharging a fluid in the processing container until the inside of the processing container reaches a second discharge ultimate pressure which is different from the first discharge ultimate pressure and at which vaporization of the processing fluid in the supercritical state does not occur, and then supplying the processing fluid into the processing container until the inside of the processing container reaches a second supply ultimate pressure which is higher than the second discharge ultimate pressure and at which vaporization of the processing fluid in the processing container does not occur.

The foregoing summary is illustrative only and is not intended to be in any way limiting, in addition to the illustrative aspects, embodiments, and features described above, further aspects, embodiments, and features will become apparent by reference to the drawings and the following detailed description.

### BRIEF DESCRIPTION Of THE DRAWINGS

FIG. 1 is a cross-sectional plan view illustrating an overall configuration of a cleaning processing system.

FIG. 2 is a perspective view illustrating the external appearance of an exemplary processing container of a supercritical processing apparatus.

FIG. 3 is a view illustrating an exemplary configuration of the overall system of the supercritical processing apparatus.

FIG. 4 is a block diagram illustrating a functional configuration of a controller.

FIGS. 5A to 5D are enlarged cross-sectional views for explaining a drying mechanism of IPA, in which patterns are schematically illustrated as recesses of a wafer.

FIG. 6 is a graph illustrating an exemplary relationship among time, a pressure in the processing container, and a consumption amount of a processing fluid (CO₂) in a first drying processing example.

FIG. 7 is a graph illustrating a relationship among a concentration, a critical temperature, and a critical pressure of CO₂.

FIG. 8 is a graph illustrating a relationship among a concentration, a critical temperature, and a critical pressure of CO₂.

FIG. 9 is a graph illustrating a relationship among a concentration, a critical temperature, and a critical pressure of CO₂.

FIG. 10 is a graph illustrating time and pressure in the processing container in a second drying processing example.

FIG. 11 is a cross-sectional view for explaining a state of IPA filled in the patterns of the wafer.

FIG. 12 is a graph illustrating time and pressure in the processing container in a third drying processing example.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made without departing from the spirit or scope of the subject matter presented here.

The present disclosure has been made under such circumstances, and the present invention is to provide a substrate processing apparatus and a substrate processing method capable of performing a drying processing for removing a liquid from a substrate rising a processing fluid in a supercritical state in a short time while suppressing consumption of the processing fluid, and a recording medium.

According to an aspect of the present disclosure, there is provided a substrate processing method that performs a drying processing of removing a liquid from a substrate using a processing fluid in a supercritical state in a processing container. The substrate processing method includes a first processing step of discharging a fluid in the processing container until an inside of the processing container reaches a first discharge ultimate pressure at which vaporization of the processing fluid in the supercritical state present in the processing container does not occur, and then supplying the processing fluid into the processing container until the inside of the processing container reaches a first supply ultimate pressure which is higher than the first discharge ultimate pressure and at which vaporization of the processing fluid in the processing container does not occur; and after the first processing step, a second processing step of discharging a fluid in the processing container until the inside of the processing container reaches a second discharge ultimate pressure which is different from the first discharge ultimate pressure and at which vaporization of the processing fluid in the supercritical state does not occur, and then supplying the processing fluid into the processing container until the inside of the processing container reaches a second supply ultimate pressure which is higher than the second discharge ultimate pressure and at which vaporization of the processing fluid in the processing container does not occur.

In the above-described substrate processing method, the first discharge ultimate pressure is higher than the second discharge ultimate pressure.

In the above-described substrate processing method, the first discharge ultimate pressure is lower than the second discharge ultimate pressure.

The above-described substrate processing method further includes, after the second processing step, a third processing step of discharging a fluid in the processing container until the inside of the processing container reaches a third discharge ultimate pressure which is lower than the second discharge ultimate pressure and at which vaporization of the processing fluid in the supercritical state does not occur, and then supplying the processing fluid into the processing container until the inside of the processing container reaches a third supply ultimate pressure winch is higher than the third discharge ultimate pressure and at which vaporization of the processing fluid in the processing container does not occur.

In the above-described substrate processing method, at least one of a timing of discharging the fluid in the processing container until the inside of the processing container reaches the first discharge ultimate pressure and a timing of discharging the fluid in the processing container until the inside of the processing container reaches the second discharge ultimate pressure is determined based on a result of an preliminary experiment.

In the above-described substrate processing method, the first supply ultimate pressure and the second supply ultimate pressure are higher than a maximum value of a critical pressure of the processing fluid in the processing container.

In the above-described substrate processing method, the processing fluid is supplied into the processing container in a substantially horizontal direction.

According to another aspect of the present disclosure, there is provided a substrate processing apparatus including: a processing container into which a substrate having a recess is carried, the recess being filled with a liquid; a fluid supply unit that supplies a processing fluid in a supercritical state into the processing container; a fluid discharge unit that discharges a fluid in the processing container; and a controller that controls the fluid supply unit and the fluid discharge unit to perform a drying processing using the processing fluid in the supercritical state, so that the liquid is removed from the substrate in the processing container. The controller controls the fluid supply unit and the fluid discharge unit to perform a first processing step of discharging a fluid in the processing container until an inside of the processing container reaches a first discharge ultimate pressure at which vaporization of the processing fluid in the supercritical state present in the processing container does not occur, and then supplying the processing fluid into the processing container until the inside of the processing container reaches a first supply ultimate pressure which is higher than the first discharge ultimate pressure and at winch vaporization of the processing fluid in the processing container does not occur; and after the first processing step, a second processing step of discharging a fluid in the processing container until the inside of the processing container reaches a second discharge ultimate pressure which is different from the first discharge ultimate pressure and at which vaporization of the processing fluid in the supercritical state docs not occur, and then supplying the processing fluid into the processing container until the inside of the processing container reaches a second supply ultimate pressure which is higher than the second discharge ultimate pressure and at winch vaporization of the processing fluid in the processing container does not occur.

According to yet another aspect of the present disclosure, there is provided a non-transitory computer-readable storage medium that stores a program that, when executed, cause a computer to execute a substrate liquid processing method that performs a drying processing of removing a liquid from a substrate using a processing fluid in a supercritical state in a processing container. The method includes: a first processing step of discharging a fluid in the processing container until an inside of the processing container reaches a first discharge ultimate pressure at which vaporization of the processing fluid in the supercritical state present in the processing container does not occur, and then supplying the processing fluid into the processing container until the inside of the processing container reaches a first supply ultimate pressure which is higher than the first discharge ultimate pressure and at which vaporization of the processing fluid in the processing container does not occur; and after the first processing step, a second processing step of discharging a fluid in the processing container until the inside of the processing container reaches a second discharge intimate pressure which is different from the first discharge ultimate pressure and at which vaporization of the processing fluid in the supercritical state does not occur, and then supplying the processing fluid into the processing container until the inside of the processing container reaches a second supply ultimate pressure which is higher than the second discharge ultimate pressure and at which vaporization of the processing fluid in the processing container does not occur.

According to the present disclosure, it is possible to perform a drying processing for removing liquid from a substrate using a processing fluid in a supercritical state in a short time while suppressing consumption of processing fluid.

Hereinafter, an exemplary embodiment of the present disclosure will be described with reference to the drawings. The configuration illustrated in the drawings attached to the present specification may include portions in which sizes and scales are changed from the actual ones for convenience of illustration and ease of understanding.

### [Configuration of Cleaning Processing System]

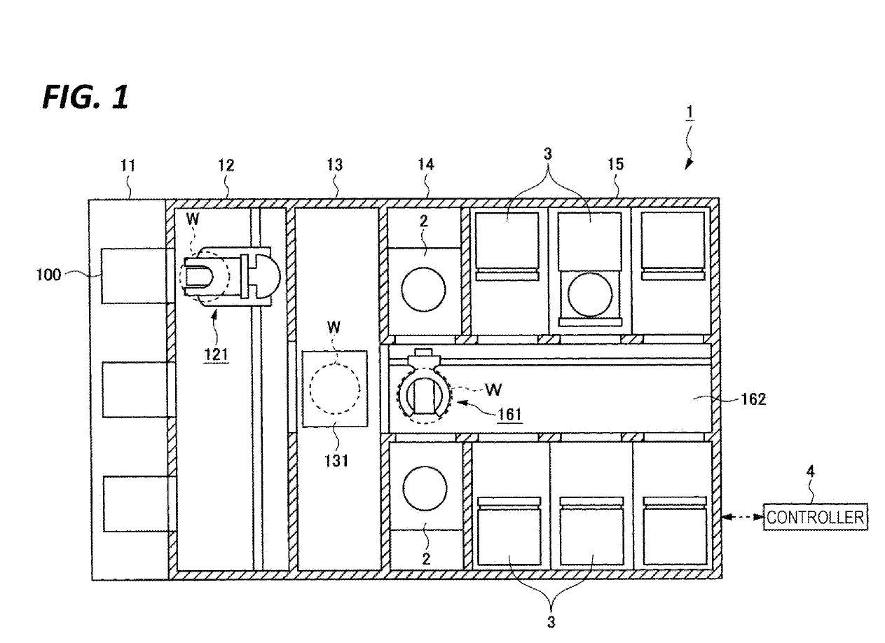

FIG. 1 is a cross-sectional plan view illustrating an overall configuration of a cleaning processing system 1.

The cleaning processing system 1 includes a plurality of cleaning apparatuses 2 (two cleaning apparatuses 2 in the example illustrated in FIG. 1) that supply a cleaning liquid to waters W to perform a cleaning processing, and a plurality of supercritical processing apparatuses 3 (six supercritical processing apparatuses 3 in the example illustrated in FIG. 1) that remove a drying prevention liquid (IPA: isopropyl alcohol in the present exemplary embodiment) attached to the wafers W after the cleaning processing by bringing the drying prevention liquid into contact with a supercritical processing fluid (carbon dioxide (CO₂) in the present exemplary embodiment).

In the cleaning processing system 1, front opening unified pods (FOUPs) 100 are placed in a placing section 11, and the wafers W stored in the FOUPs 100 are delivered to a cleaning processing section 14 and a supercritical processing section 15 via a carry-in/out section 12 and a delivery section 13. In the cleaning processing section 14 and the supercritical processing section 15, the wafers W are first carried into the cleaning apparatuses 2 provided in the cleaning processing section 14 and are subjected to a cleaning processing. Then, the wafers W are carried into the supercritical processing apparatuses 3 and are subjected to a drying processing to remove the IPA from the wafers W. In FIG. 1, reference numeral “121” denotes a first conveyance mechanism that conveys the wafer W between the FOUPs 100 and the delivery section 13, and reference numeral “131” denotes a delivery shelf that plays a role as a buffer on winch the wafers W conveyed between the carry-in/out section 12 and the cleaning processing section 14 and the supercritical processing section 15 are temporarily placed.

A wafer conveyance path 162 is connected to an opening of the delivery section 13, and the cleaning processing section 14 and the supercritical processing section 15 are provided along the wafer conveyance path 162. In the cleaning processing section 14, one cleaning apparatus 2 is disposed on each side of the wafer conveyance path 162. Thus, a total of two cleaning apparatuses 2 are installed. Meanwhile, in the supercritical processing section 15, three supercritical processing apparatuses 3 functioning as substrate processing apparatuses for performing a drying processing for removing IPA from the wafers W are disposed on each side of the wafer conveyance path 162. Thus, a total of six supercritical processing apparatuses 3 are installed. A second conveyance mechanism 161 is disposed in the water conveyance path 162, and the second conveyance mechanism 161 is provided to be movable inside the wafer conveyance path 162. The wafers W placed on the delivery shell 131 are received by the second conveyance mechanism 161, and the second conveyance mechanism 161 carries the wafers W into the cleaning apparatuses 2 and the supercritical processing apparatuses 3. The number and arrangement of the cleaning apparatuses 2 and the supercritical processing apparatuses 3 are not particularly limited, but depending on the number of waters W processed per unit time and the processing time of each cleaning apparatus 2 and each supercritical processing apparatus 3, an appropriate number of cleaning apparatuses 2 and supercritical processing apparatuses 3 are arranged in a suitable manner.

Each cleaning apparatus 2 is configured as a single wafer type apparatus that cleans the wafers W one by one by, for example, spin cleaning. In this case, the cleaning processing of a wafer W may be performed by supplying a chemical liquid for cleaning or a rinse liquid for washing out a chemical liquid to the processing surface of the wafer W at an appropriate timing while rotating the water W about the vertical axis in a state where the water W is horizontally held. The chemical liquid and the rinse liquid used in the cleaning apparatus 2 are not particularly limited. For example, an SC1 liquid (i.e., a mixed liquid of ammonia and hydrogen peroxide water), which is an alkaline chemical liquid, may be supplied to the wafer W to remove particles and organic contaminants from the wafer W. Thereafter, deionized water (DIW), which is a rinse liquid, may be supplied to the wafer W to wash out the SC1 liquid from the wafer W. Further, a diluted hydrofluoric acid (DHF) aqueous solution, which is an acidic chemical solution, may be supplied to the wafer W to remove a natural oxide film, and then DIW may be supplied to the wafers W to wash out the dilute hydrofluoric acid aqueous solution from the wafer W.

Then, when the cleaning processing with the chemical liquid is completed, the cleaning apparatus 2 stops the rotation of the wafer W, and supplies IPA as a drying prevention liquid to the wafer W to replace the DIW remaining on the processing surface of the wafer W with the IPA. At this time, a sufficient amount of the IPA is supplied to the wafer W, so that the surface of the wafer W having patterns of the semiconductor formed thereon is in a state of being filled with the IPA, and a liquid film of the IPA is formed on the surface of the wafer W. The wafer W is carried out from the cleaning apparatus 2 by the second conveyance mechanism 161 while maintaining the state of being filled with the IPA.

The IPA applied to the surface of the wafer W in this manner serves to prevent drying of the wafer W. In particular, in order to prevent the so-called pattern collapse from occurring on the wafer W due to vaporization of the IPA during the conveyance of the wafer W from the cleaning apparatus 2 to the supercritical processing apparatus 3, the cleaning apparatus 2 applies a sufficient amount of the IPA to the wafer W such that an IPA film having a relatively large thickness is formed on the surface of the wafer W.

The wafer W carried out from the cleaning apparatus 2 is earned into a processing container of the supercritical processing apparatus 3 by the second conveyance mechanism 161 In a state of being filled with IPA, and is subjected to a drying processing of the IPA in the supercritical processing apparatus 3.

### [Substrate Processing Apparatus]

Hereinafter, details of the drying processing using a supercritical fluid performed in the supercritical processing apparatus 3 will be described. First, a configuration example of a processing container into which the wafer W is carried in the supercritical processing apparatus 3 will be described, and then a configuration example of the overall system of the supercritical processing apparatus 3 will be described.

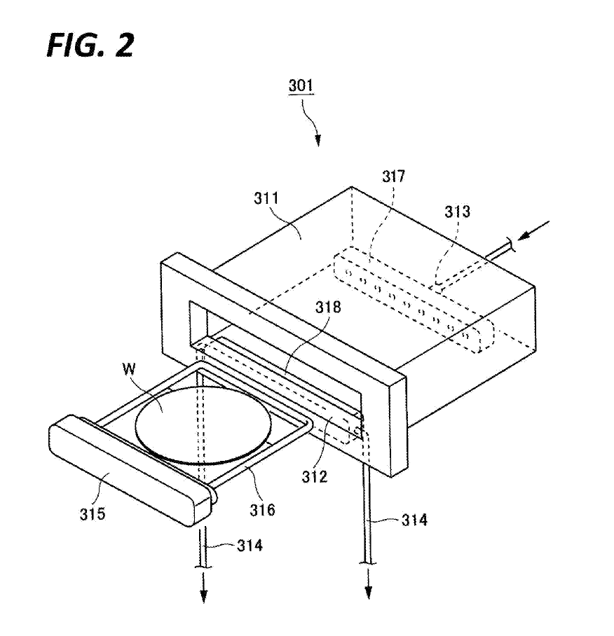

FIG. 2 is a perspective view illustrating the external appearance of an exemplary processing container 301 of a supercritical processing apparatus 3.

The processing container 301 includes a case-type container body 311 having an opening 312 for carry-in/out of a wafer W formed therein, a holding plate 316 that horizontally holds the wafer W, which is a processing target, and a cover member 315 that supports the holding plate 316 and seals the opening 312 when the water W is carried into the container body 311.

The container body 311 is a container in which a processing space capable of accommodating a wafer W having a diameter of, for example, 300 mm is formed, and a supply port 313 and a discharge port 314 are provided in the wall portion. The supply port 313 and the discharge port 314 arc connected to a supply line for circulating the processing fluid provided on the upstream side and the downstream side of the processing container 301, respectively. Although one supply port 313 and two discharge ports 314 are illustrated in FIG. 2, the numbers of the supply port 313 and the discharge port 314 are not particularly limited.

A fluid supply header 317 is provided in one wall portion of the container body 311 to communicate with the supply port 313, and a fluid discharge header 318 is provided in the other wall portion of the container body 311 to communicate with the discharge port 314. The fluid supply header 317 is provided with a plurality of openings, and the fluid discharge header 318 is also provided with a plurality of openings. The fluid supply header 317 and the fluid discharge header 318 are provided to face each other. The fluid supply header 317 serving as a fluid supply unit supplies the processing fluid into the container body 311 in a substantially horizontal direction. The horizontal direction as used herein is a direction perpendicular to the vertical direction in which gravity acts, and is usually parallel to the direction in which the flat surface of the wafer W held by the holding plate 316 extends. The fluid discharge header 318 serving as a fluid discharge portion for discharging the fluid in the processing container 301 guides and discharges the fluid in the container body 311 to the outside of the container body 311. The fluid to be discharged to the outside of the container body 311 through the fluid discharge header 318 includes, in addition to the processing fluid supplied into the container body 311, IPA dissolved in the processing fluid from the surface of the wafer W. Since the processing fluid is supplied into the container body 311 from the openings of the fluid supply header 317 and the fluid is discharged from the container body 311 through the openings of the fluid discharge header 318 in this manner, a laminar flow of the processing fluid flowing substantially in parallel with the surface of the wafer W is formed in the container body 311.

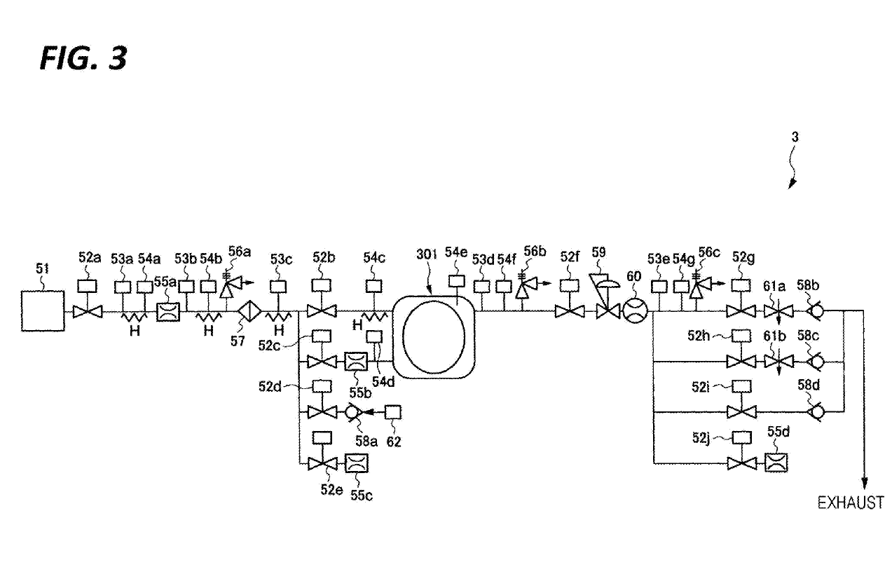

From the viewpoint of reducing the load that may be applied to the wafer W at the time of supplying the processing fluid into the container body 311 and discharging the fluid from the container body 311, it is desirable to provide a plurality of fluid supply headers 317 and a plurality of fluid discharge headers 318. In the supercritical processing apparatus 3 illustrated in FIG. 3 to be described later, two supply lines for supplying the processing fluid are connected to the processing container 301. In FIG. 2, however, only one supply port 313 and one fluid supply header 317 connected to one supply line are illustrated in order to facilitate understanding.

The processing container 301 further includes a pressing mechanism (not illustrated). The pressing mechanism plays a role of pressing the cover member 313 toward the container body 311 against the internal pressure caused by the processing fluid in the supercritical state supplied into the processing space, and sealing the processing space. In addition, for example, a heat insulating material or a tape heater may be provided on the surface of the container body 311 such that the processing fluid supplied into the processing space is able to maintain the temperature in the supercritical state.

FIG. 3 is a view illustrating an exemplary configuration of the overall system of the supercritical processing apparatus 3.

A fluid supply tank 51 is provided on the upstream side of the processing container 301, and a processing fluid is supplied from the fluid supply tank 51 to a supply line for circulating the processing fluid in the supercritical processing apparatus 3. Between the fluid supply tank 51 and the processing container 301, a flow on/off valve 52a, an orifice 55a, a filter 57, and a flow on/off valve 52b are sequentially provided from the upstream side to the downstream side. The terms “upstream side” and “downstream side” as used herein refer to a flow direction of the processing fluid in the supply line as a reference.

The flow on/off valve 52a is a valve for adjusting on/off of the supply of the processing fluid from the fluid supply tank 51. In an open state, the processing fluid is allowed to flow to the supply line on the downstream side, and in a closed state, the processing fluid is not allowed to the supply line on the downstream side. When the flow on/off valve 52a is in the open state, a high-pressure processing fluid of, for example, about 16 to 20 MPa (megapascals) is supplied from the fluid supply tank 51 to the supply hue via the flow on/off valve 52a. The orifice 55a plays a role of adjusting the pressure of the processing fluid supplied from the fluid supply tank 51, so that the processing fluid the pressure of which is adjusted to, for example, about 16 MPa may flow through the supply fine on the downstream side of the orifice 55a. The filter 57 removes foreign matters contained in the processing fluid sent from the orifice 55a and flows a clean processing fluid to the downstream side.

The flow on/off valve 52b is a valve tor adjusting on/off of the supply of the processing fluid to the processing container 30b The supply line extending from the flow on/off valve 52b to the processing container 301 is connected to the supply port 313 illustrated in FIG 2, and the processing fluid from the flow on/off valve 52b is supplied into the container body 311 of the processing container 301 via the supply port 313 and the fluid supply header 317 illustrated in FIG. 2.

In the supercritical processing apparatus 3 illustrated in FIG. 3, the supply line diverges between the filter 57 and the flow on/off valve 52b. That is, the supply hue between the filter 57 and the flow on/off valve 52b diverges to a supply line conceded to the processing container 301 via a flow on/off valve 52c and an orifice 55b, a supply line connected to a purge device 62 via a flow on/off valve 52d and a cheek valve 58a, and a supply line connected to the outside via a flow on/off valve 52e and an orifice 55c.

The supply line connected to the processing container 301 via the flow on/off valve 52c and the orifice 55b is an auxiliary flow path for supplying the processing fluid to the processing container 301. For example, when a relatively large amount of processing fluid is supplied to the processing container 301, for example, at the beginning of the supply of the processing fluid to the processing container 301, the flow on/off valve 52c is adjusted to the open state, so that the processing fluid the pressure of which is adjusted by the orifice 55b may be supplied to the processing container 301.

The supply line connected to the purge device 62 via the flow on/off valve 52d and the check valve 58a is a flow path for supplying an inert gas (e.g., nitrogen) to the processing container 301, and is utilized while the supply of the processing fluid from the fluid supply tank 51 to the processing container 301 is stopped. For example, in a case where the processing container 301 is filled with an inert gas and maintained in a clean state, the flow on/off valve 52d and the flow on/off valve 52b are adjusted to the open state, so that the inert gas sent from the purge device 62 to the supply line is supplied to the processing container 301 via the check valve 58a, the flow on/off valve 52d, and the flow on/off valve 52b.

The supply line connected to the outside via the flow on/off valve 52e and the orifice 55e is a flow path for discharging the processing fluid from the supply line. For example, when the processing fluid remaining in the supply line between the flow on/off valve 52a and the flow on/off valve 52b is discharged to the outside at the time of turning off the power supply of the supercritical processing apparatus 3, the flow on/off valve 52e is adjusted to the open state, so that the supply line between the flow on/off valve 52a and the flow on/off valve 52b is communicated with the outside.

On the downstream side of the processing container 301, a flow on/off valve 52f, an exhaust adjustment valve 59, a concentration measurement sensor 60 and a flow on/off valve 52g are sequentially provided from the upstream side to the downstream side.

The flow on/off valve 52f is a valve for adjusting on/off of the discharge of the processing fluid from the processing container 301. When the processing fluid is discharged from the processing container 301, the flow on/off valve 52f is adjusted to the open state, whereas when the processing fluid is not discharged from the processing container 301, the flow on/off valve 52f is adjusted to the closed state. A supply hue extending between the processing container 301 and the flow on/off valve 52f is connected to the discharge port 314 illustrated in FIG. 2. The fluid in the container body 311 of the processing container 301 is sent toward the flow on/off valve 52f via the fluid discharge header 318 and the discharge ports 314 illustrated in FIG. 2.

The exhaust adjustment valve 59 is a valve for adjusting the discharge amount of the fluid from the processing container 301, and may be constituted by, for example, a back pressure valve. The opening degree of the exhaust adjustment valve 59 is adaptively adjusted under the control of a controller 4 depending on a desired discharge amount of the fluid from the processing container 301. In the present embodiment, as will be described later, a processing of discharging the fluid from the processing container 301 is performed until the pressure of the fluid in the processing container 301 reaches a predetermined pressure. Therefore, when the pressure of the fluid in the processing container 301 readies a predetermined pressure, the exhaust adjustment valve 59 may stop the discharge of the fluid from the processing container by adjusting the opening degree so as to shift from the open state to the closed state.

The concentration measurement sensor 160 is a sensor for measuring the concentration of the IPA contained in the fluid sent from the exhaust adjustment valve 59.

The flow on/off valve 52g is a valve for adjusting on/off of the discharge of the fluid from the processing container 301 to the outside. When the fluid is discharged to the outside, the flow on/off valve 52g is adjusted to the open state, whereas when the fluid is not discharged, the flow on/off valve 52g is adjusted to the closed state. An exhaust adjustment needle valve 61a and a check valve 58b are provided on the downstream side of the flow on/off valve 52g. The exhaust adjustment needle valve 61a is a valve for adjusting the discharge amount of the fluid sent to the outside via the flow on/off valve 52g, and the opening degree of the exhaust adjustment needle valve 61a is adjusted depending on a desired discharge amount of the fluid. The check valve 58b is a valve for preventing backflow of the discharged fluid and plays a role of reliably discharging the fluid to the outside.

In the supercritical processing apparatus 3 illustrated in FIG 3, the supply line diverges between the concentration measurement sensor 60 and the flow on/off valve 52g. That is, the supply line between the filter 60 and the flow on/off valve 52b diverges to a supply line connected So the outside via a flow on/off valve 52h, a supply line connected to the outside via a flow on/off valve 52i, and a supply line connected to the outside via a flow on/off valve 52j.

Similarly to the flow on/off valve 52g, the flow on/off valve 52b and the flow on/off valve 52i are valves for adjusting, on/off of the discharge of the fluid to the outside. An exhaust adjustment needle valve 61b and a check valve 58c are provided on the downstream side of the flow on/off valve 52h to adjust the discharge amount of the fluid and to prevent backflow of the fluid. A cheek valve 58d is provided on the downstream side of the flow on/off valve 52i to prevent backflow of the fluid. The flow on/off valve 52j is also a valve for adjusting on/off of the discharge of the fluid to the outside, and an orifice 55d is provided on the downstream side of the flow on/off valve 52j, so that the fluid may be discharged from the flow on/off valve 52j to the outside via the orifice 55d. In the example illustrated in FIG. 3, however, the destination of the fluid sent to the outside via the flow on/off valve 52g, the flow on/off valve 52h, and the flow on/off valve 52i is different from the destination of the fluid sent to the outside via the flow on/off valve 52j. Therefore, it is also possible to send the fluid to a recovery device (not illustrated) via, for example, the flow on/off valve 52g, the flow on/off valve 52b, and the flow on/off valve 52i, while discharging the fluid to the atmosphere via the flow on/off valve 52j.

When the fluid is discharged from the processing container 301, one or more of the flow on/off valve 52g, the flow on/off valve 52h, the flow on/off valve 52i, and the flow on/off valve 52j is adjusted to the open state. In particular, when the power of the supercritical processing apparatus 3 is turned off, the flow on/off valve 52j may be adjusted to the open state so as to discharge the fluid reclaiming in the supply line between the concentration measurement sensor 60 and the flow on/off valve 52g to the outside.

Pressure sensors and temperature sensors are provided at various positions of the above-described supply line to detect the pressure and the temperature of the fluid. In the example illustrated in FIG. 3, a pressure sensor 53a and a temperature sensor 54a are provided between the flow on/off valve 52a and the orifice 55a, a pressure sensor 53b and a temperature sensor 54b are provided between the orifice 55a and the filter 57, a pressure sensor 53c is provided between the flow on/off valve 52b and the processing container 301, a temperature sensor 54c is provided between the flow on/off valve 52b and the processing container 301, and a temperature sensor 54d is provided between the orifice 55b and the processing container 301. Further, a pressure sensor 53d and a temperature sensor 54f are provided between the processing container 301 and the flow on/off valve 52f, and a pressure sensor 53e and a temperature sensor 54g are provided between the concentration measurement sensor 60 and the flow on/off valve 52g. Furthermore, a temperature sensor 54e is provided to detect the temperature of the fluid in the container body 311, which is the inside of the processing container 301.

Further heaters H are provided at arbitrary positions where the processing fluid flows in the supercritical processing apparatus 3. In FIG. 3, the heaters H are provided in the supply line on the upstream side of the processing container 301 (i.e., between the flow on/off valve 52a and the orifice 55a, between the orifice 55a and the filter 57, between the filter 57 and the flow on/off valve 52b, and between the flow on/off valve 52b and the processing container 301). However, the heaters H may be provided at other portions including the processing container 301 and the supply line on the downstream side of the processing container 301. Therefore, the heaters H may be provided in the entire flow path until the processing fluid supplied from the fluid supply tank 51 is discharged to the outside. Further, in particular, from the viewpoint of adjusting the temperature of the processing fluid to be supplied to the processing container 301, the heaters H may be provided at positions where the temperature of the processing fluid flowing on the upstream side of the processing container 301 can be adjusted.

Furthermore, a safety valve 56a is provided between the orifice 55a and the inter 57, and a safety valve 56b is provided between the processing container 301 and the flow on/off valve 52f and a safety valve 56c is provided between the concentration measurement sensor 60 and the flow on/off valve 52g. These safety valves 56a to 56c play a role of making the supply line communicate with the outside so that the fluid in the supply line is urgently discharged to the outside in a case of an abnormality, for example, when the pressure in the supply line becomes excessive.

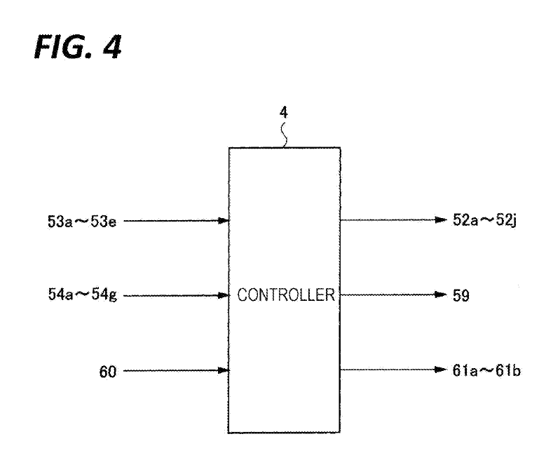

FIG. 4 is a block diagram illustrating a functional configuration of a conn-oiler 4. The controller 4 receives measurement signals from the various elements illustrated in FIG. 3 and transmits control instruction signals to the various elements illustrated in FIG. 3. For example, the controller 4 receives the measurement results of the pressure sensors 53a to 53e, the temperature sensors 54a to 54g, and the concentration measurement sensor 60. Further, the controller 4 transmits a control instruction signal to the flow on/off valves 52a to 52j, the exhaust adjustment valve 59, and the exhaust adjustment needle valves 61a and 61b. Signals that may be transmitted and received by the controller 4 are not particularly limited. For example, when the safety valves 56a to 56c are able to open and close based on the control instruction signal from the controller 4, the controller 4 transmits a control instruction signal to the safety valves 56a to 56c as necessary. However, when the open/close drive system of the safety valves 56a to 56c is not based on a signal control, the controller 4 does not transmit a control instruction signal to the safety valves 56a to 56c.

### [Supercritical Drying Processing]

Next, the drying mechanism of IPA using the processing fluid in the supercritical state will be described.

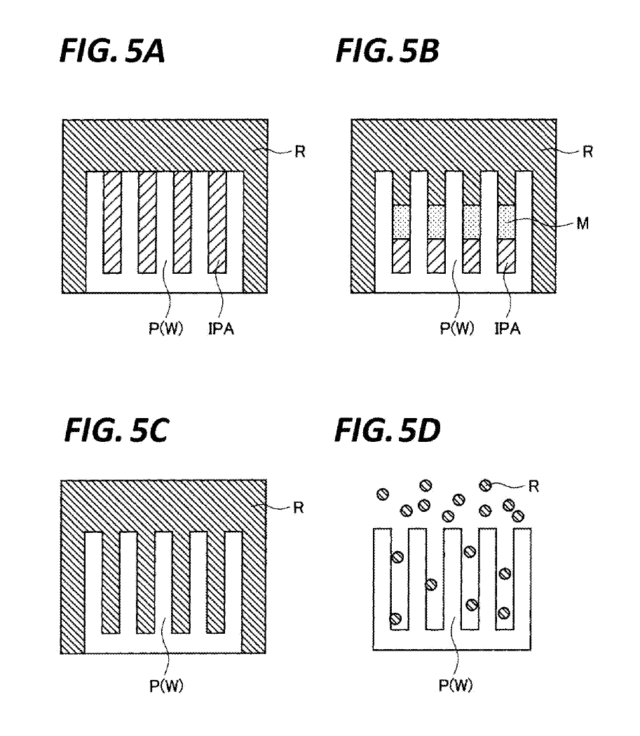

FIGS. 5A to 5D are enlarged cross-sectional views for explaining a drying mechanism of IPA, in which patterns P are schematically illustrated as recesses of the wafer W.

Initially when a processing fluid R in a supercritical state is introduced into the container body 311 of the processing container 301 in the supercritical processing apparatus 3, only IPA is filled between the patterns P as illustrated in FIG. 5A.

The IPA between the patterns P are gradually dissolved in the processing fluid R by coming into contact with the processing fluid R in the supercritical state, and gradually replaced with the processing fluid R, as illustrated in FIG. 5B. At this time, there is a mixed fluid M in a state where the IPA and the processing fluid R are mixed, in addition to the IPA and the processing fluid R, between the patterns P.

As the replacement of the IPA with the processing fluid R progresses between the patterns P, the IPA is removed between the patterns P, and finally only the processing fluid R in the supercritical state are filled between the patterns P as illustrated in FIG. 5C.

After the IPA is removed between the patterns P, the pressure inside the container body 311 is lowered to atmospheric pressure, so that the processing fluid R changes from the supercritical state to the gas state as illustrated in FIG. 5D, and the gaps between the patterns P is occupied only by the gas. Thus, the IPA between the patterns P is removed, and the drying processing of the wafer W is completed.

On the background of the mechanisms illustrated in FIGS. 5A to 5D, the supercritical processing apparatus 3 of the present exemplary embodiment performs a drying processing of IPA as follows.

That is, the substrate processing method performed by the supercritical processing apparatus 3 includes a step of carrying a wafer W in which the IPA for drying prevention is filled between the patterns P into the container body 311 of the processing container 301, a step of supplying a processing fluid in a supercritical state into the container body 311 via the fluid supply unit (i.e., the supply tank 51, the flow on/off valve 52a, the flow on/off valve 52b, and the fluid supply header 317), and a step of performing a drying processing using the processing fluid in the supercritical state to remove the IPA in the container body 311.

In particular, in the drying processing of IPA using the processing fluid in the supercritical state (i.e., the supercritical drying processing), the processing fluid is supplied to and discharged from the container body 311 of the processing container 301 such that a high pressure that does not cause gas-liquid separation is maintained between the patterns P. More specifically, the IPA is gradually removed between the patterns P of the wafer W by alternately repeating a plurality of times a pressure decreasing step of discharging the processing fluid from the container body 311 to decrease the pressure inside the container body 311, and a pressure increasing step of supplying the processing fluid into the container body 311 to increase the pressure inside the container body 311. In the pressure increasing step, the processing fluid is supplied into the container body 311 such that the pressure between the patterns P is higher than the maximum value of the critical pressure of the two-component system of the processing fluid and the IPA. On the other hand, in the pressure decreasing step, the fluid is discharged from the container body 311 such that the pressure between the patterns P is gradually decreased as the decrease in the concentration of the IPA and the increase in the processing fluid concentration in the mixed fluid between the patterns P progress by the repetitive performance of the pressure decreasing step and the pressure increasing step. Even in the pressure deceasing step, however, the pressure between the patterns P is maintained at a pressure at which the fluid between the patterns P maintains the non-gas state.

Hereinafter, typical drying processing examples will be described. In each of the following drying processing examples, CO₂ is used as a processing fluid.

### [First Drying Processing Example]

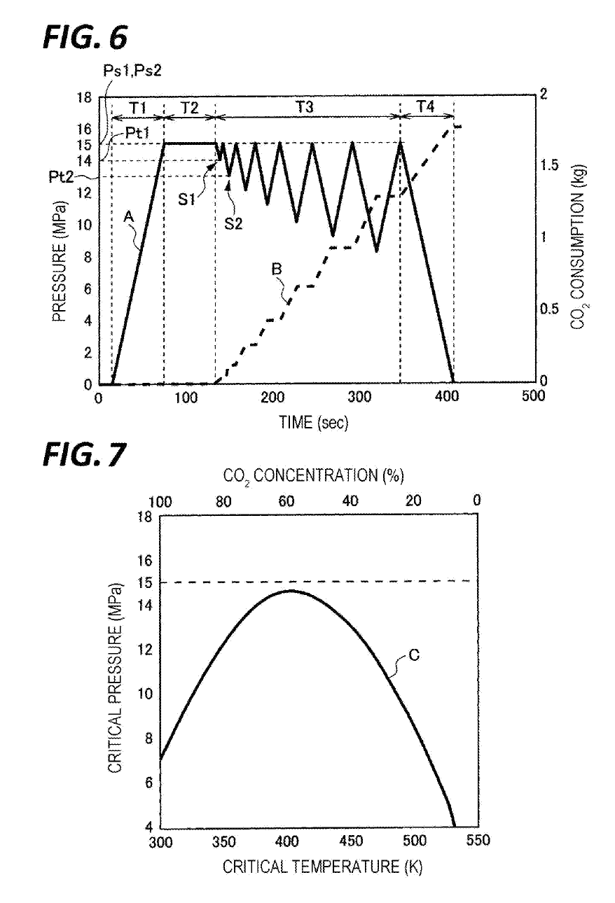

FIG. 6 is a graph illustrating an exemplary relationship among time, a pressure in the processing container 301 (i.e., in the container body 311), and a consumption amount of the processing fluid (CO₂) in the first drying processing example. Curve A illustrated in FIG. 6 represents a relationship between the time (horizontal axis; sec) and the pressure in the processing container 301 (vertical axis: MPa) in the first drying processing example. Curve B illustrated in FIG. 6 represents a relationship between the time (horizontal axis; sec) and the consumption amount of the processing fluid CO₂ (vertical axis; MPa) in the first drying processing example.

In the present drying processing example, a fluid introduction step T1 is first performed, so that CO₂ is supplied from the fluid supply tank 51 into the processing container 301 (i.e., into the container body 311).

In the fluid introduction step T1, the controller 4 performs a control so as to bring the flow on/off valve 52a, the flow on/off valve 52b, the flow on/off valve 52c, and the flow on/off valve 52f illustrated in FIG. 3 into the open state, and bring the flow on/off valve 52d and the flow on/off valve 52e illustrated in FIG. 3 into the closed state. Further, the controller 4 performs a control so as to bring the flow on/off valves 52g to 52i into the open state and bring the flow on/off valve 52ⱼ into the closed state. Further, the controller 4 performs a control so as to bring the exhaust adjustment needle valves 61a and 61b into the open state. Further, the controller 4 adjusts the opening degree of the exhaust adjustment valve 59 such that the pressure in the processing container 30i reaches a desired pressure (15 MPa in the example illustrated in FIG. 6) in order to maintain the supercritical state of CO₂ in the processing container 301).

In the fluid introduction step T1 illustrated in FIG. 6, in the processing container 301, the IPA on the wafer W begins to dissolve into CO₂ in the supercritical state. When the supercritical CO₂ and the IPA on the water W begin to mix, the ratio of IPA and CO₂ locally vary in the mixed fluid of CO₂ and IPA, so that the critical pressure of CO₂ may also have locally various values. Meanwhile, in the fluid introduction step T1, the supply pressure of CO₂ into the processing container 301 is adjusted to a pressure higher than all the critical pressure of CO₂ (i.e., a pressure higher than the maximum value of the critical pressure). Therefore, regardless of the ratio of IPA and CO₂ in the mixed fluid, the CO₂ in the processing container 301 becomes a supercritical state or a liquid state, rather than a gas state.

Then, after the fluid introduction step T1, a fluid maintenance step T2 is performed, and the pressure in the processing contained 301 is maintained constant until the concentration of IPA and the concentration of CO₂ in the mixed fluid between the patterns P of the wafer W reach desired concentrations (e.g., the concentration of IPA is 30% or less, and the concentration of CO₂ is 70% or more).

In the fluid maintenance step T2, the pressure in the processing container 301 is adjusted to such an extent that the CO₂ in the processing container 301 is maintained in the supercritical state, in the example illustrated in FIG. 6, the pressure in the processing container 301 is maintained at 15 MPa. In the fluid maintenance step T2, the controller 4 performs a control so as to bring the flow on/off valve 52b and the flow on/off valve 52f illustrated in FIG. 3 into the closed state. Thus, the supply and discharge of the CO₂ into and from the processing container 301 is stopped. The open and closed states of the other various valves are the same as the open and closed states in the fluid introduction step T1 described above.

Then, after the fluid maintenance step T2, a fluid supply and discharge step T3 is performed, so that a pressure decreasing step of discharging the fluid from the processing container 301 to decrease the pressure in the processing container 301 and a pressure increasing step of supplying CO₂ into the processing container 301 are repeated.

In the pressure decreasing step, the fluid in a state where CO₂ and IPA are mixed is discharged from the processing container 301. Meanwhile, in the pressure increasing step, fresh CO₂, which does not contain IPA, is supplied from the fluid supply tank 51 to the processing container 301. In this manner, removal of the IPA from the top of the wafer W is promoted by positively discharging the IPA from the processing container 301 in the pressure decreasing step and supplying IPA-free CO₂ into the processing container 301 in the pressure increasing step.

The number of times of repetition of the pressure decreasing step and the pressure increasing step in the fluid supply and discharge step T3 is not particularly limited. However the drying processing of the present example includes at least the following first and second processing steps S1 and S2 at the beginning of the fluid supply and discharge step T3. The controller 4 controls the fluid supply unit (i.e., the flow on/off valves 52a to 52b illustrated in FIG. 3) and the fluid discharge unit (i.e., the flow on/off valves 52f to 52j and the exhaust adjustment valve 59 illustrated in FIG. 3) to perform the drying processing including the processing step S1 and the second processing step S2 using CO₂ in the supercritical state.

That is, in the first processing step S1 performed immediately after the fluid maintenance step T2, the fluid in the processing container 301 is discharged until the inside of the processing container 301 reaches a first discharge ultimate pressure Pt1 (e.g., 14 MPa) at which vaporization of the CO₂ in the supercritical state does not occur, and then CO₂ is supplied into the processing container 301 until the inside of the processing container 301 reaches a first supply ultimate pressure Ps1 (e.g., 15 MPa) winch is higher than the first discharge ultimate pressure Pt1 and at which vaporization of the CO₂ in the processing container 301 does not occur.

Meanwhile, in the second processing step S2 performed immediately after the first processing step S1, the fluid in the processing container 301 is discharged until the inside of the processing container 301 reaches a second discharge ultimate pressure Pt2 (e.g., 13 MPa) which is different from the first discharge ultimate pressure Pt1 and at which vaporization of the CO₂ in the supercritical state does not occur, and then CO₂ is supplied into the processing container 301 until the inside of the processing container 301 reaches a second supply ultimate pressure Ps2 (e.g., 15 MPa) which is higher than the second discharge ultimate pressure Pt2 and at which vaporization of the CO₂ in the processing container 301 does not occur.

In particular, in the present drying processing example, the first discharge ultimate pressure Pt1 in the pressure decreasing step of the first processing step S1 is set to be higher than the second discharge ultimate pressure Pt2 in the pressure decreasing step in the second processing step S2 (i.e., “Pt1>Pt2” is satisfied).

FIG. 7 is a graph illustrating a relationship among a concentration, a critical temperature, and a critical pressure of CO₂. The horizontal axis of FIG. 7 represents a critical temperature (K: Kelvin) of CO₂ and a concentration (%) of CO₂, and the vertical axis of FIG. 7 represents a critical pressure (MPa) of CO₂. The concentration of CO₂ in FIG. 7 represents a mixing ratio of CO₂, and the concentration of CO₂ is represented by the ratio of CO₂ in the mixed gas of IPA and CO₂.

Curve C in FIG. 7 represents a relationship among the concentration, the critical temperature, and the critical pressure of CO₂. When the state of CO₂ is above curve C, the CO₂ has a pressure higher than the critical pressure. When the state of CO₂ is below curve C, the CO₂ has a pressure lower than the critical pressure.

As described above, in the present drying processing example, the IPA on the wafer W is gradually removed by repeatedly performing the pressure decreasing step of discharging CO₂ from the processing container 301 to decrease the pressure in the processing container 301 and the pressure increasing step of introducing CO₂ from the fluid supply tank 51 into the processing container 301 (i.e., the container body 311) to increase the pressure in the processing container 301. In this drying processing, in each pressure increasing step, the supply pressure of CO₂ to the processing container 301 is set to be higher than the maximum value of the critical pressure of CO₂. Therefore, the first supply ultimate pressure Ps1 and the second supply ultimate pressure Ps2 described above are adjusted to pressures higher than all the critical pressure represented by curve C in FIG. 7 (i.e., higher than the maximum value of the critical pressure of CO₂ (e.g., 15 MPa)). Thus, it is possible to prevent the vaporization of CO₂ in the processing container 301.

As described above, in the mixed fluid of CO₂ and IPA, the CO₂ and the IPA exist locally at various ratios, and the value of the critical pressure of CO₂ may also vary locally. However, in the present exemplary embodiment, the supply pressure of CO₂ into the processing container 301 is adjusted to a pressure higher than the maximum value of the critical pressure of CO₂. Thus, regardless of the ratio of IPA and CO₂ in the mixed fluid, CO₂ becomes a supercritical state or a liquid state and does not become a gas state.

Meanwhile, in each pressure decreasing step, CO₂ is discharged from the processing container 301 such that the CO₂ between the patterns P has a pressure higher than the critical pressure. That is, the pressure in the processing container 301 (discharge ultimate pressure) in each pressure decrease step is adjusted to a pressure higher than the critical pressure of CO₂. In general, as the IPA removal between patterns P progresses, the concentration of the IPA in the mixed fluid between the patterns P tends to gradually decrease, and the concentration of CO₂ tends to gradually increase. On the other hand, as is clear from curve C in FIG. 7, the critical pressure of CO₂ fluctuates according to the concentration of CO₂, and particularly when the concentration of CO₂ is larger than approximately 60%, the critical pressure gradually decreases as the concentration of CO₂ increases.

Further, as the difference between the pressure in the processing container 301 in the pressure increasing step (i.e., the supply ultimate pressure) and the pressure in the processing container 301 in the pressure decreasing step (i.e., the discharge ultimate pressure) increases, the discharge amount of the fluid from the processing container 301 increases. As the discharge amount of the fluid from the processing; container 301 increases, the discharge amount of IPA from the processing container 301 increases. Thus, the amount of CO₂ supplied into the processing container 301 in the subsequent pressure increasing step may be increased. Therefore, as the pressure difference in the processing container 301 between the pressure decreasing step and the pressure increasing step that are continuously performed is increased, replacement from IPA to CO₂ may be effectively promoted. Thus, the drying processing of IPA may be performed for a short time.

In the plurality of pressure decreasing steps repeatedly performed in the fluid supply and discharge step T3 illustrated in FIG. 6, the pressure of CO₂ is gradually decreased and the discharge amount of CO₂ from the processing container 301 is gradually increased, in a range where the CO₂ between the patterns P maintains the non-gas state, based on the relationship between the concentration and the critical pressure of CO₂.

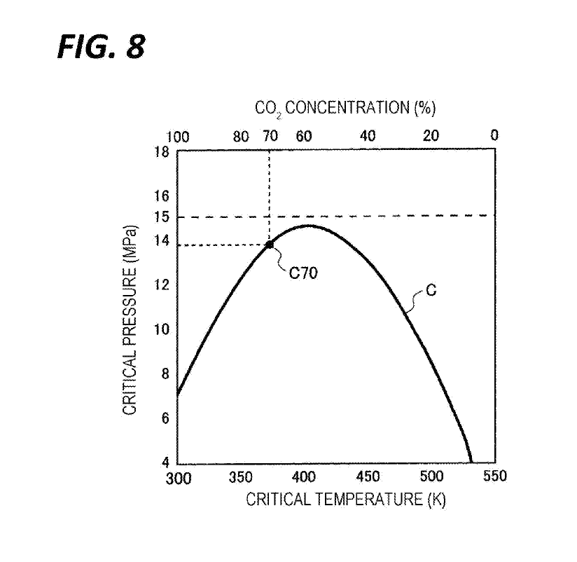

For example, in the first processing step S1 illustrated in FIG. 6, assuming that the concentration of CO₂ in the mixed fluid between the patterns P is 70%, the critical pressure of CO₂ between the patterns P is lower than approximately 14 MPa as indicated by point C70 in FIG. 8. Therefore, the first discharge ultimate pressure Pt1 in the pressure decreasing step of the first processing step S1 is set to a pressure higher than the critical pressure indicated by point C70 in FIG. 8 (e.g., 14 MPa). As a result, it is possible to discharge the fluid from the processing container 301 in a state where the CO₂ between the patterns P is prevented from vaporizing in the pressure decreasing step of the first processing step S1.

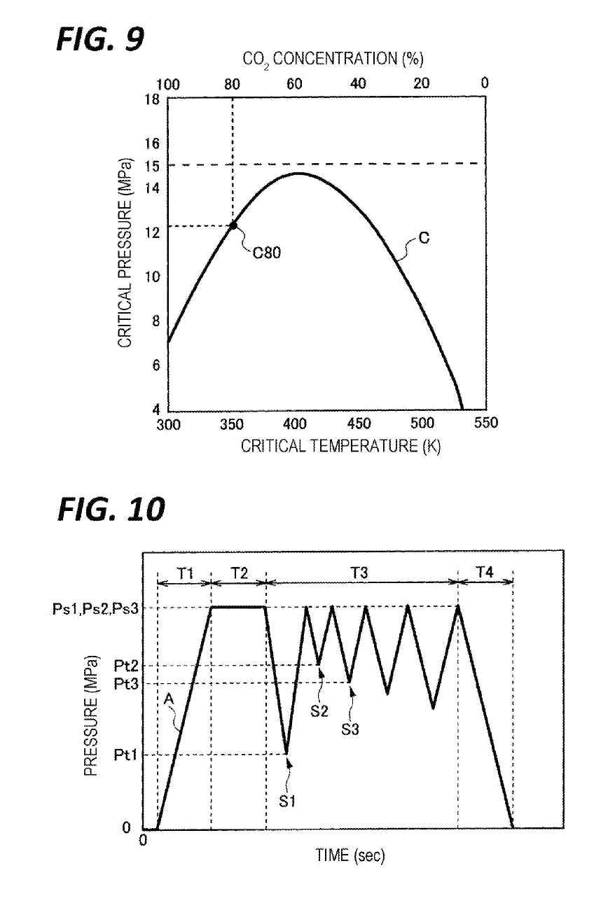

Meanwhile, in the second processing step S2 performed thereafter, assuming that the concentration of CO₂ in the mixed fluid between the patterns P is 80%, the critical pressure of CO₂ between the patterns P is approximately 12 MPa as indicated by point C80 in FIG. 9. Therefore, the first discharge ultimate pressure Pt2 in the pressure decreasing step of the first processing step S2 is set to a pressure higher than the critical pressure indicated by point C80 in FIG. 9 (e.g., 13 MPa). As a result, it is possible to discharge the fluid from the processing container 301 in a state where the CO₂ between the patterns P is prevented from vaporizing in the pressure decreasing step of the first processing step S2. In particular, since the discharge amount of the fluid in the pressure decreasing step in the second processing step S2 is larger than the discharge amount of the fluid in the pressure decreasing step in the first processing step S1, IPA may be removed more effectively in the second processing step S2.

In the example illustrated in FIG. 6, the pressure in the processing container 301 in each pressure increasing step is increased to the same pressure (i.e., 15 MPa), but the pressure in the processing container 301 is not necessarily the same in every pressure increasing step. However, the pressure in the processing container 301 in each pressure increasing step is increased to a pressure higher than the maximum value of the critical pressure of CO₂, and the CO₂ in the processing container 301 maintains the non-gas state.

Further, in the example illustrated in FIG. 6, the pressure in the processing container 301 in each pressure decreasing step is gradually decreased to a lower pressure, but it is not necessary to gradually decrease the pressure in the processing container 301 in the pressure decreasing step. However, from the viewpoint of removing IPA in a short time, it is desirable that the discharge amount of the fluid from the processing container 301 in the pressure decreasing step is large. As the pressure in the processing container 301 is decreased in the pressure decreasing step, the discharge amount of the fluid is increased. Therefore, considering that the concentration of CO₂ in the mixed fluid between the patterns P gradually increases with the progress of the fluid supply and discharge step T3 and considering the characteristic of the critical temperature-critical pressure of CO₂ illustrated in FIG. 7, it is desirable that the pressure in the processing container 301 is gradually decreased to a lower pressure.

In the example illustrated in FIG. 6, when CO₂ is supplied into the processing container 301 up to the first supply ultimate pressure Ps1 (15 MPa) in the pressure increasing step of the first processing step S1, the concentration of the IPA between the patterns P is diluted immediately to 20% or less. Therefore, immediately after the pressure increasing step in the first processing step S1 is performed, the pressure decreasing step in the second processing step S2 is performed, and the fluid is discharged from the processing container 301. Further, even in the processing steps after the first processing step S1, the pressure decreasing steps and the pressure increasing steps are performed in the same manner, and each pressure decreasing step is started immediately alter the immediately preceding pressure increasing step is completed, and each pressure increasing step is started immediately after the immediately preceding pressure decreasing step.

The above-described pressure decreasing steps and pressure increasing steps are performed by the controller 4 that controls the opening/closing of the flow on/off valve 52b, the flow on/off valve 52f and the exhaust adjustment valve 59 illustrated in FIG. 3. For example, in the case where the pressure increasing steps are performed by supplying CO₂ into the processing container 301, the flow on/off valve 52b is opened and the flow on/off valve 52f is closed under the control of the controller 4. Meanwhile, in the case where the pressure decreasing steps are performed by discharging CO₂ from the processing container 301, the flow on/off valve 52b is closed and the flow on/off valve 52f is opened under the control of the controller 4. In the pressure decreasing steps, the exhaust adjustment valve 59 is controlled by the controller 4 in order to strictly discharge the fluid in the processing container 301 to a desired discharge ultimate pressure.

In particular, in order to perform a strict control in the pressure decreasing steps, the controller 4 adjusts the opening degree of the exhaust adjustment valve 59 based on the measurement result of the pressure sensor 53d provided between the processing container 301 and the flow on/off valve 52f. That is, the pressure in the supply line communicating with the inside of the processing container 301 is measured by the pressure sensor 53d. The controller 4 calculates the opening degree of the exhaust adjustment valve 59 necessary for adjusting the inside of the processing container 301 to a desired pressure from the measurement value of the pressure sensor 53d and transmits a control instruction signal to the exhaust adjustment valve 59. The exhaust adjustment valve 59 adjusts the opening degree based on the control instruction signal from the controller 4, so that the inside of the processing container 301 is adjusted to a desired pressure. Therefore, the pressure inside the processing container 301 is adjusted to a desired pressure with high accuracy.

As described above, the controller 4 controls the supply amount and the discharge amount of CO₂ with respect to the processing container 301 in the course of repeating the above-described pressure decreasing steps and pressure increasing steps such that the CO₂ between the patterns P always has a pressure higher than the critical pressure Therefore, it is possible to prevent the CO₂ between the patterns P from vaporizing, so that the CO₂ between the patterns P is always in a non-gas state during the fluid supply and discharge step T3. Pattern collapse that may occur in the wafer W is caused by a gas-liquid interface that may exist between the patterns P. Generally, the pattern collapse is caused by contact of a gaseous processing fluid between the patterns P (CO₂ in this example) with liquid IPA. According to the present drying processing example, as described above, CO₂ between the patterns P is always in a non-gas state while the fluid supply and discharge step T3 is performed, so that pattern collapse does not occur in principle.

It is difficult to directly measure the concentration of CO₂ between the patterns P while the fluid supply and discharge step T3 is performed. Therefore, it is possible to determine the timing of performing the pressure decreasing steps and the pressure increasing steps based on the results of experiments performed in advance and perform the pressure decreasing steps and the pressure increasing steps based on the determined timing. For example, at least one of a timing of discharging the fluid in the processing container 301 until the inside of the processing container 301 reaches the first discharge ultimate pressure Pt1 and a timing of discharging the fluid in the processing container 301 until the inside of the processing container 301 reaches the second discharge ultimate pressure Pt2 may be determined based on the result of the experiments performed in advance.

Further, the temperature of the CO₂ in the processing container 301 may be adjusted to a temperature at which the CO₂ is able to maintain the supercritical state by a heater (not illustrated) provided in the processing container 301. In that case, the heater may be controlled by the controller 4 based on the measurement result of the temperature sensor 54e that measures the temperature of the fluid in the processing container 301, so that the heating temperature of the heater is adjusted. However, the temperature of the fluid in the processing container 301 is not necessarily adjusted under the control of the controller 4. Even when the temperature of CO₂ in the processing container 301 becomes lower than the critical temperature, CO₂ in the processing container 301 takes a non-gas state such as liquid. Therefore, the pattern collapse caused by the gas-liquid interface between the patterns P does not occur even if the temperature of the CO₂ in the processing container 301 becomes lower than the critical temperature. However, since the temperature of CO₂ in the processing container 301 is one of the factors that influence the density of CO₂, the temperature of CO₂ in the processing container 301 may be positively adjusted by means of a device such as a heater from the viewpoint of improving the replacement efficiency from IPA to CO₂.

Then, the fluid discharge step T4 is performed at a stage where the IPA between the patterns P is replaced with CO₂ in the fluid supply and discharge step T3 and the IPA remaining in the processing container 301 is sufficiently reduced (e.g., a stage where the concentration of the IPA in the processing container 301 is 0% to several %), so that the inside of the processing container 301 is returned to the atmospheric pressure. As a result, it is possible to vaporize CO₂ while preventing the IPA remaining in the processing container 301 from being re-attached to the wafer W. Thus, only a gas exists between the patterns P as illustrated in FIG. 5D.

In the fluid discharge step T4, the controller 4 performs a control so as to bring the flow on/off valves 52a to 52e into the closed state, bring the flow on/off valves 52f to 52i into the open state, bring the flow on/off valve 52j into the closed state, and bring the exhaust adjustment needle valves 61a and 61b into the open state.

By performing the fluid introduction step T1, the fluid maintenance step T2, the fluid supply and discharge step T3, and the fluid discharge step T4 as described above, the drying processing for removing IPA from the wafer W is completed.

The timing at which each of the fluid introduction step T1, the fluid maintenance step T2, the fluid supply and discharge step T3, and the fluid discharge step T4 is performed, the duration of each step, and the number of times of repetition of the pressure decreasing steps and the pressure increasing steps in the fluid supply and discharge step T3 may be determined by any method. The controller 4 may determine the timing at which each step is performed, the duration of each step, the number of times of repetition of the pressure decreasing steps and the pressure increasing steps in the fluid supply and discharge step T3 based on, for example, the “concentration of the IPA contained in the fluid discharged from the processing container 301” measured by the concentration measurement sensor 60. Further, the controller 4 may determine the timing at which each step is performed, the duration of each step, the number of times of repetition of the pressure decreasing steps and the pressure increasing steps in the fluid supply and discharge step T3 based on the results of experiments performed in advance.

According to the above-described supercritical processing apparatus 3 (i.e., the substrate processing apparatus) and the substrate processing method, it is possible to perform the drying processing in a short time while suppressing the consumption amount of the processing fluid. Thus, it is also possible to effectively suppress occurrence of pattern collapse.

According to the experiments of the inventors of the present disclosure, in the ease of drying IPA on the wafer W by continuously supplying and discharging CO₂ in a supercritical state of 10 MPa with respect to the processing container 301 at a rate of 0.5 kg per minute based on the related art. It took about 30 minutes, and it was necessary to consume tens of kg of CO₂. On the other hand, in the case of removing IPA on the wafer W based on the present drying processing example as illustrated in FIG. 6, it was possible to properly dry the wafer W by repeating seven times “a processing step including one pressure decreasing step and one pressure increasing step” in the fluid supply and discharge step T3. The total processing time was about 7 minutes, and the consumption amount of CO₂ was about 1.7 kg. As described above, the substrate processing apparatus and the substrate processing method of the present exemplary embodiment may remarkably promote the reduction of the processing time and the reduction of the consumption of CO₂ (processing fluid).

### [Second Drying Processing Example]

FIG. 10 is a graph illustrating time and pressure in the processing container 301 in the second drying processing example. Curve A illustrated In FIG. 10 represents a relationship between the time (horizontal axis; sec) and the pressure in the processing container 301 (vertical axis; MPa) in the second drying processing example.

In the present drying processing example, a detailed description of the same or similar contents as in the above-described first drying processing example will be omitted.

In the present drying processing example, similarly to the above-described first drying processing example, the fluid introduction step T1, the fluid maintenance step T2, the fluid supply and discharge step T3, and the fluid discharge step T4 are sequentially performed. However, in the fluid supply and discharge step T1 of the present drying processing example, the first discharge ultimate pressure Pt1 in the pressure decreasing step of the first processing step S1 performed immediately after the fluid maintenance step T2 is lower than the second discharge ultimate pressure Pt2 in the subsequent pressure decreasing step of the second processing step S2.

In the fluid supply and discharge step T3 of the drying processing, the pressure decreasing steps and the pressure increasing steps of the third processing step S3 performed immediately after the second processing step S2 are performed as follows. That is, after the second processing step S2, the fluid in the processing container is discharged until the inside of the processing container 301 reaches a third discharge ultimate pressure Pt3 which is the third discharge ultimate pressure Pt3 at which the vaporization of the CO₂ in the supercritical state does not occur and which is lower than the second discharge ultimate pressure Pt2. Thereafter, CO₂ is supplied into the processing container 301 until the inside of the processing container 301 reaches a third supply ultimate pressure Ps3 which is higher than the third discharge ultimate pressure Pt3 and at which the vaporization of CO₂ in the processing container 301 does not occur.

The third supply ultimate pressure Ps3 is set to the same pressure as the first supply ultimate pressure Ps1 and the second supply ultimate pressure Ps2, and may be set to, for example, 15 MPa as in the above-described first drying processing example.

In the present drying processing example, a ramp-up drying processing is performed, and the discharge ultimate pressure in the pressure decreasing step of the first processing step S1 that is first performed (i.e., the first discharge ultimate pressure Pt1) indicates the lowest pressure. That is, the largest amount of the fluid is discharged from the processing container 301 in the pressure decreasing step of the first processing step SI among the pressure decreasing steps in the fluid supply and discharge step T3. As a result, it is possible to efficiently remove the IPA on the film formed above the patterns P of the wafer W.

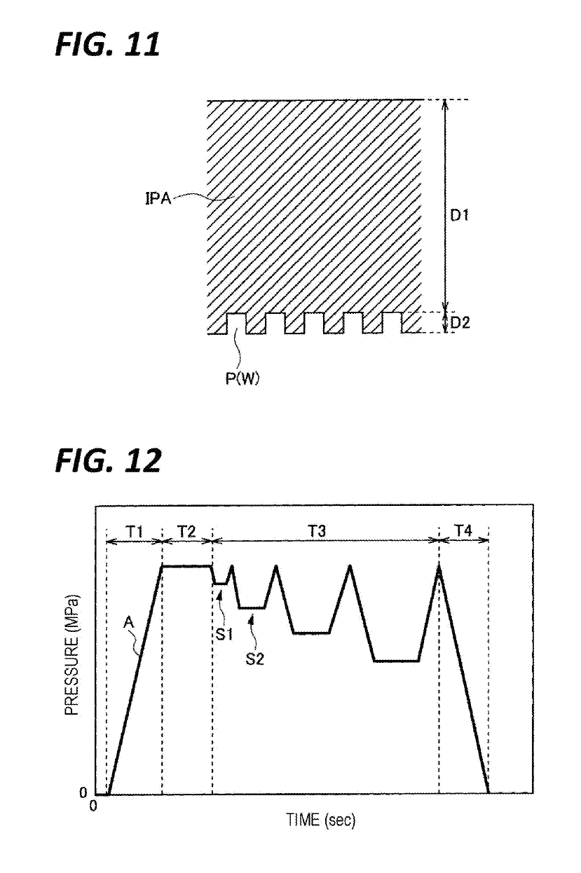

FIG. 11 is a cross-sectional view for explaining a state of IPA filled on the patterns P of the wafer W.

On the patterns P of the wafer W carried into the supercritical processing apparatus 3, an IPA film having a thickness D1 is formed. The thickness D1 of the IPA film is much larger than the thickness D2 of the patterns P, and the thickness D1 is generally about several tens of times the thickness D2. The portion of the IPA film above the patterns P also needs to be removed by the supercritical processing apparatus 3, but the removal amount of the IPA film above the patterns P is extremely large compared to the removal amount of IPA between the patterns P. Further, the IPA between the patterns P is able to be removed only after the portion of the IPA film above the patterns P has been removed.

Therefore, in the fluid supply and discharge step T3, it is desirable that the IPA film above the patterns P is first removed as much as possible by the first processing step S1, and the IPA between the patterns P is then removed by the second processing step S2 and subsequent processing steps. Therefore, in the present drying processing example, first, in the first processing step S1, a large amount of fluid is discharged from the processing container 301 in the pressure decreasing steps, and a large amount of CO₂ is supplied to the processing container 301 in the pressure increasing steps, so that the IPA film above the patterns P is largely removed.

When removing the IPA film above the patterns P, IPA is filled between the patterns P. Thus, there is no concern about pattern collapse. However, in consideration of the possibility that, in addition to the IPA film above the patterns P, a part of the IPA between the patterns P is also removed in the first processing step S1, the first discharge ultimate pressure Pt1 in the pressure decreasing steps of the first processing step S1 is set to be higher than the critical pressure of the CO₂ in the processing container 301.

The pressure decreasing steps and the pressure increasing steps in the processing steps other than the first processing step S1 are performed in the same manner as in the above-described first drying processing example. That is, the pressure in the processing container 301 in each pressure increasing step of the fluid supply and discharge step T3 is increased to the same pressure (i.e., 15 MPa), which is higher than the maximum value of the critical pressure of CO₂. In the pressure decreasing steps in the second processing step S2 and the subsequent processing steps of the fluid supply and discharge step T3, the pressure in the processing container 301 is decreased to a lower pressure. However, the pressure between the patterns P is maintained at a pressure at which the CO₂ between the patterns P maintains the non-gas state.

As described above, according to the present drying processing example, it is possible to efficiently remove the IPA film formed above the patterns P of the water W. Thus, it is possible to shorten the processing time of the drying processing of IPA.

### [Third Drying Processing Example]

FIG. 12 is a graph illustrating time and pressure in the processing container 301 in the third drying processing example. Curve A illustrated in FIG. 12 represents a relationship between the time (horizontal axis; sec) and the pressure in the processing container 301 (vertical axis; MPa) in the third drying processing example.

In the present drying processing example, a detailed description of the same or similar contents as in the above-described first drying processing example will be omitted.

In the present drying processing example, similarly to the above-described first drying processing example, the fluid introduction step T1, the fluid maintenance step T2, the fluid supply and discharge step T3, and the fluid discharge step T4 are sequentially performed. However, in the fluid supply and discharge step T3 of the present drying processing example, a pressure maintaining step is performed between the pressure decreasing step and the pressure increasing step to maintain the pressure in the processing container 301 substantially constant.

In each pressure maintaining step, the inside of the processing container 301 is maintained at the same pressure as the discharge ultimate pressure of the immediately preceding pressure decreasing step.

By performing the pressure maintaining step, it is possible to efficiently remove the IPA from the wafer W.

For example, the processing fluid used for the drying processing may be a fluid other than CO₂, and an arbitrary fluid capable of removing the drying prevention liquid filled in the recesses of the substrate in the supercritical state may be used as a processing fluid. Further, the drying prevention liquid is not limited to IPA, and any liquid available as a drying prevention liquid may be used.

In addition, in the exemplary embodiments and the modifications described above, the present disclosure is applied to the substrate processing apparatus and the substrate processing method, but the application target of the present disclosure is not particularly limited. For example, the present disclosure may also be applied to a program for causing a computer to execute the above-described substrate processing method, and a computer readable not-transitory recording medium in which such a program is recorded.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing method that performs a drying processing of removing a liquid from a substrate using a processing fluid in a supercritical state in a processing container, the method comprising:
a first processing step of discharging a fluid in the processing container until an inside of the processing container reaches a first discharge ultimate pressure at which vaporization of the processing fluid in the supercritical state present in the processing container does not occur, and then supplying the processing fluid into the processing container until the inside of the processing container reaches a first supply ultimate pressure which is higher than the first discharge ultimate pressure and at which vaporization of the processing fluid in the processing container does not occur; and
after the first processing step, a second processing step of discharging a fluid in the processing container until the inside of the processing container reaches a second discharge ultimate pressure which is different from the first discharge ultimate pressure and at which vaporization of the processing fluid in the supercritical state does not occur, and then supplying the processing fluid into the processing container until the inside of the processing container reaches a second supply ultimate pressure winch is higher than the second discharge ultimate pressure and at which vaporization of the processing fluid in the processing container does not occur.

2. The substrate processing method of claim 1, wherein the first discharge ultimate pressure is higher than the second discharge ultimate pressure.

3. The substrate processing method of claim 1, wherein the first discharge ultimate pressure is lower than the second discharge ultimate pressure.

4. The substrate processing method of claim 3, further comprising:
after the second processing step, a third processing step of discharging a fluid in the processing container until the inside of the processing container reaches a third discharge ultimate pressure which is lower than the second discharge ultimate pressure and at which vaporization of the processing fluid in the supercritical state does not occur, and then supplying the processing fluid into the processing container until the inside of the processing container reaches a third supply ultimate pressure which is higher than the third discharge ultimate pressure and at which vaporization of the processing fluid in the processing container does not occur.

5. The substrate processing method of claim 1, wherein at least one of a timing of discharging the fluid in the processing container until the inside of the processing container reaches the first discharge ultimate pressure and a tuning of discharging the fluid in the processing container until the inside of the processing container reaches the second discharge ultimate pressure is determined based on a result of a preliminary experiment.

6. The substrate processing method of claim L wherein the first supply ultimate pressure and the second supply ultimate pressure are higher than a maximum value of a critical pressure of the processing fluid in the processing container.

7. The substrate processing method of claim 1, wherein the processing fluid is supplied into the processing container in a substantially horizontal direction.

8. A substrate processing apparatus comprising:
a processing container into which a substrate having a recess is carried, the recess being filled with a liquid:
a fluid supply unit that supplies a processing fluid in a supercritical state into the processing container:
a fluid discharge unit that discharges a fluid in the processing container: and
a controller that controls the fluid supply unit and the fluid discharge unit to perform a drying processing using the processing fluid in the supercritical state, so that the liquid is removed from the substrate in the processing container,
wherein the controller controls the fluid supply unit and the fluid discharge unit to perform:
a first processing step of discharging a fluid in the processing container until an inside of the processing container reaches a first discharge ultimate pressure at which vaporization of the processing fluid in the supercritical state present in the processing container does not occur, and then supplying the processing fluid into the processing container until the inside of the processing container reaches a first supply ultimate pressure which is higher than the first discharge ultimate pressure and at which vaporization of the processing fluid in the processing container does not occur; and
after the first processing step, a second processing step of discharging a fluid in the processing container until the inside of the processing container reaches a second discharge ultimate pressure which is different from the first discharge ultimate pressure and at which vaporization of the processing fluid in the supercritical state does not occur; and then supplying the processing fluid into the processing container until the inside of the processing container reaches a second supply ultimate pressure which is higher than the second discharge ultimate pressure and at which vaporization of the processing fluid in the processing container does not occur.

9. A non-transitory computer-readable storage medium that stores a program that, when executed, cause a computer to execute a substrate liquid processing method that performs a drying processing of removing a liquid from a substrate using a processing fluid in a supercritical state in a processing container, the method comprising:
a first processing step of discharging a fluid in the processing container until an inside of the processing container reaches a first discharge ultimate pressure at which vaporization of the processing fluid in the supercritical state present in the processing container does not occur, and then supplying the processing fluid into the processing container until the inside of the processing container reaches a first supply ultimate pressure which is higher than the first discharge ultimate pressure and at which vaporization of the processing fluid in the processing container does not occur; and
after the first processing step, a second processing step of discharging a fluid in the processing container until the inside of the processing container reaches a second discharge ultimate pressure which is different from the first discharge ultimate pressure and at which vaporization of the processing fluid in the supercritical state does not occur, and then supplying the processing fluid into the processing container until the inside of the processing container reaches a second supply ultimate pressure which is higher than the second discharge ultimate pressure and at which vaporization of the processing fluid in the processing container does not occur.
